(19) United States
(12) Patent Application Publication
(10) Pub. No.: US 2019/0182589 A1
(43) Pub. Date: Jun. 13, 2019

(54) EXCURSION CONTROL BASED ON AN AUDIO SIGNAL BANDWIDTH ESTIMATE OBTAINED FROM BACK-EMF ANALYSIS

(71) Applicant: TEXAS INSTRUMENTS INCORPORATED, Dallas, TX (US)

(72) Inventor: Supriyo PALIT, Kolkata (IN)

(21) Appl. No.: 16/041,955

(22) Filed: Jul. 23, 2018

(30) Foreign Application Priority Data
Dec. 7, 2017 (IN) 201741043943

(51) Int. Cl. H04R 3/00; H03F 3/68; H03F 3/187; H04R 29/00

(52) U.S. Cl. CPC H04R 3/007; H03F 3/68; H03F 2200/03; H04R 29/003; H03F 3/187

(57) ABSTRACT

A system includes a filter circuit configured to adjust digitized audio signal values based on filter parameters. The system also includes a filter parameter selection circuit configured to determine an audio signal bandwidth estimate based on back-EMF analysis and to supply different sets of filter parameters to the filter circuit based on the audio signal bandwidth estimate and a predetermined threshold. The system also includes a digital-to-analog converter (DAC) configured to convert an output of the filter circuit into an analog audio signal to be amplified.

### CROSS-REFERENCE TO RELATED APPLICATIONS

The present application claims priority to India Provisional Patent Application No. 201741043943, filed Dec. 7, 2017, titled “Novel Narrow Band Stabilization Algorithm for Adaptive Parameter Estimation of Loudspeakers,” which is hereby incorporated herein by reference in its entirety.

### BACKGROUND

Speakers in consumer products (e.g., speakers in a mobile phone or tablet) are prone to mechanical failures if driven at high power levels. As the movement of speaker diaphragm increases at high power levels, the likelihood of damage, such as bottoming of the suspension, increases. Despite being prone to mechanical failures, there is an ever increasing demand in the market for louder audio from smaller speakers.

To prevent mechanical failures of speakers, existing system designs attempt to maintain the power level to the speaker voice coil within a safe operating range. Such attempts can be passive or dynamic. Dynamically controlling the power level to the speaker voice coil to avoid mechanical failures is challenging due to several variables, including changes to speaker characteristics over time due to temperature, aging and manufacturing tolerances. These variations often cause misalignment in speaker protection systems.

One strategy to account for changes in speaker characteristics over time is to track speaker parameters in real-time and then respond to changes by adjusting the speaker protection system. Previous efforts to track speaker parameters include using real-time voltage and current measurements and an adaptive algorithm to characterize a speaker. While some existing speaker parameter tracking algorithms are reliable for wideband input signals, accounting for narrowband input signals (e.g., piano music) continues to be problematic, Efforts to improve narrowband signal detection and response options are ongoing.

### SUMMARY

In accordance with at least one example of the disclosure, a system comprises a filter circuit configured to adjust digitized audio signal values based on filter parameters. The system also comprises a filter parameter selection circuit configured to determine an audio signal bandwidth estimate based on back-EMF analysis and to supply different sets of filter parameters to the filter circuit based on the audio signal bandwidth estimate and a predetermined threshold. The system also comprises a digital-to-analog converter (DAC) configured to convert an output of the filter circuit into an analog audio signal to be amplified.

In accordance with at least one example of the disclosure, an amplifier device comprises circuitry configured to determine an audio signal bandwidth estimate based on back-EMF analysis, to obtain different sets of filter parameters, to select one of the different sets of filter parameters based on the audio signal bandwidth estimate and a predetermined threshold, to perform a filter operation on digitized audio signal values based on a selected one of the different sets of filter parameters, and to output a result of the filter operation. The amplifier device also comprises a DAC configured to convert the result of the filter operation to an analog audio signal. The amplifier device also comprises an amplifier configured to amplify the analog audio signal.

In accordance with at least one example of the disclosure, an audio signal amplification method comprises receiving a digitized audio signal. The method also comprises determining if the digitized audio signal is a narrowband audio signal or wideband audio signal based on back-EMF analysis. In response to determining that the digitized audio signal is a wideband audio signal, a current set of filter parameters is selected. In response to determining that the digitized audio signal is a narrowband audio signal, a previous set of filter parameters is selected. The method also comprises filtering the digitized audio signal based on the selected set of filter parameters. The method also comprises converting a result of the filtering into an analog audio signal, and amplifying the analog audio signal.

### BRIEF DESCRIPTION OF THE DRAWINGS

For a detailed description of various examples, reference will now be made to the accompanying drawings in which:

FIG. 1 shows a block diagram of an audio system in accordance with various examples;

FIG. 2 shows a block diagram of control components for an audio system in accordance with various examples;

FIG. 3 shows a cross-sectional view of a speaker and a filter parameter selection block for the speaker in accordance with various examples;

FIG. 4 shows another block diagram of an audio system in accordance with various examples;

FIG. 5 shows a flowchart of an excursion control method in accordance with various examples;

FIG. 6 shows an audio amplification system in accordance with various examples;

FIG. 7 shows an amplifier device in accordance with various examples;

FIG. 8 shows graphs comparing broadband and narrowband portions of an audio signal and related filter parameter tracking with and without narrowband stabilization in accordance with various examples;

FIGS. 9 and 10 show graphs representing adaptation behavior without and with narrowband stabilization; and

FIG. 11 shows a flowchart of an audio signal amplification method in accordance with various examples.

### DETAILED DESCRIPTION

The disclosed examples are directed to excursion control for a speaker based on an audio signal bandwidth estimate obtained from back-EMF analysis. In at least some examples, excursion control is achieved using an audio signal amplification technique, where the audio signal input to an amplifier has been modified using a filter. More specifically, in some examples, different sets of filter parameters (e.g., filter coefficients) for the filter are selected depending on whether the audio signal bandwidth estimate indicates an audio signal is a wideband or narrowband signal. If the audio signal bandwidth estimate indicates that an audio signal is a wideband signal, then a current set of filter parameters are selected. On the other hand, if the audio signal bandwidth estimate indicates that an audio signal is a narrowband signal, then a previous set of filter parameters are selected. In some examples, the different sets of filter parameters are based on an adaptive speaker parameter estimation process. Thus, if a narrowband audio signal is detected based on back-EMF analysis, a previous set of filter parameters obtained using the adaptive speaker parameter estimation process (e.g., the last known set of filter parameters based on a wideband audio signal) is selected for the filter. On the other hand, if a wideband audio signal is detected based on back-EMF analysis, a current (e.g., new) set of filter parameters obtained using the adaptive speaker parameter estimation process is selected. As desired, the selected set of filter parameters are scaled before being provided to the filter for use with adjusting an input audio signal. In some examples, speaker test results are used to determine if scaling is applied to a selected set of filter parameters.

In some examples, filter parameter selection operations are performed by a dedicated filter parameter selection circuit or programmable component. In other examples, filter parameter selection operations are perform by a digital signal processor that executes filter parameter selection instructions stored in memory. As used herein, a “filter parameter selection circuit” corresponds to a dedicated circuit, one or more programmable components, and/or a processor that executes instructions stored in memory to achieve the gain control operations described herein. In some examples, the filter parameter selection circuit is part of an audio signal amplification system, where the audio signal amplification system includes a filter that adjusts an audio signal based on the filter parameter values provided by the filter parameter selection circuit (e.g., the filter performs a power compression operation). In some examples, filter operations are performed by a dedicated filter circuit or programmable component. In other examples, filter operations are perform by a digital signal processor that executes filter instructions stored in a memory. As used herein, a “filter circuit” corresponds to a dedicated circuit, one or more programmable components, and/or a processor that executes instructions stored in memory to achieve the filter operations described herein. As used herein, “filter coefficients” are used to define an impulse response or transfer function of a filter. The filter circuit output is eventually amplified and provided to a speaker. In some examples, the filter parameter selection circuit and the filter circuit are part of an audio signal amplifier device (e.g., one or more integrated circuits in a package) included in a consumer product such as a mobile device with a speaker. Example mobile devices include cellular phones or tablets. In different examples, an audio signal amplifier device includes other components such as analog-to-digital converters (ADCs), digital-to-analog converters (DACs), voltage and current sensors, and an amplifier.

In at least some examples, back-EMF analysis of a speaker is based on a speaker model such as:

$${H}_{BEMF} ( s ) = \frac{\frac{{Bl}^{2}}{{M}_{ms}} s}{{s}^{2} + s \frac{{R}_{ms}}{{M}_{ms}} + \frac{1}{{M}_{ms} {C}_{ms}}} , \qquad Equation ( 1 )$$

where H_{BEMF}(s) is the back-EMF impedance value, Bl is the force factor (magnetic field), Rₘₛ is the mechanical damping, Mₘₛ is the mechanical mass, Cₘₛ is the mechanical compliance, and s is the signal frequency. Using a speaker model such as Equation 1, dynamic adaptation of speaker parameters and the selection of filter parameters to be used for excursion control is possible even in narrowband audio signal scenarios as described herein. In some examples, Bl and Rₘₛ are measured using a sample speaker from a speaker lot, where an offset value or margin (Δ) is selected so that the variation of

$$\frac{{Bl}^{2}}{{R}_{ms}}$$

across speaker lot, temperature and aging is within the given bound. In some examples, Δ depends on Rₘₛ and is typically around 20%. In some examples, the offset value or margin is set based on available reliability/aging test data for a given speaker type or speaker lot.

In some examples, a back-EMF impedance transfer function for a speaker is estimated using adaptive speaker parameter estimation (e.g., based on normalized least-mean square optimization), where the parameters are constrained to keep the estimated transfer function shape as that of a band-pass filter. Accordingly, in some examples, the z-domain transfer function for the estimated back-EMF filter is of the form:

$${H}_{BEMF} ( z ) = \frac{{b}_{0} ( 1 - {z}^{- 2} )}{1 + {a}_{1} {z}^{- 1} + {a}_{2} {z}^{- 2}} , \qquad Equation ( 2 )$$

where the peak value of the estimated back-EMF filter is given as:

$${H}_{BEMF \_ Peak} = \frac{{Bl}^{2}}{{R}_{ms}} = \frac{2 {b}_{0}}{1 - {a}_{2}} . \qquad Equation ( 3 )$$

In some examples, the back-EMF analysis involves determining if

$$\frac{{Bl}^{2}}{{R}_{ms}} ( 1 - Δ ) \leq {H}_{BEMF \_ Peak} \leq \frac{{Bl}^{2}}{{R}_{ms}} ( 1 + Δ ) .$$

If so, the input audio signal is designated as a wideband signal, and the current set of filter parameters obtained from an adaptive speaker parameter estimation process are selected for use with a filter (i.e., the current filter parameters obtained from adaptive speaker parameter estimation are used as filter coefficients by the filter). On the other hand, if

$${H}_{BEMF \_ Peak} > \frac{{Bl}^{2}}{{R}_{ms}} ( 1 + Δ ) , or {H}_{BEMF \_ Peak} < \frac{{Bl}^{2}}{{R}_{ms}} ( 1 - Δ ) ,$$

then the input audio signal is designated as a narrowband signal. In such case, the most recent filter parameters obtained from a wideband audio signal are selected for use with a filter (i.e., the most recent filter parameters obtained from adaptive speaker parameter estimation for a wideband audio signal are used as filter coefficients by the filter). To provide a better understanding, various filter parameter selection options, audio signal amplifier options, and related components are described using the figures as follows.

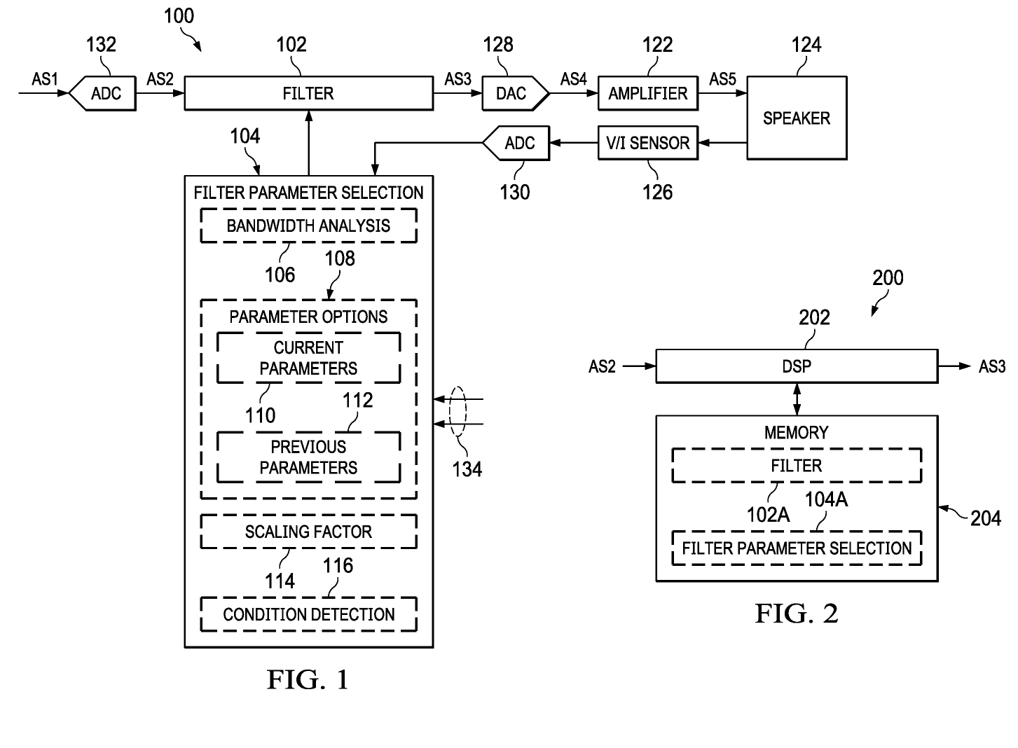

FIG. 1 shows a block diagram of a system 100 in accordance with various examples. As shown, the system 100 comprises a filter circuit 102 coupled to a filter parameter selection circuit 104. In different examples, the filter circuit 102 corresponds to a dedicated circuit, one or more programmable components, and/or a processor that executes instructions stored in memory to achieve the filter operations described herein. Likewise, in different examples, the filter parameter selection circuit 104 corresponds to a dedicated circuit, one or more programmable components, and/or a processor that executes instructions stored in memory to achieve the gain control operations described herein.

In operation, the filter circuit 102 adjusts values of a digitized audio signal (AS2) based in part on a set of filter parameters 136 or 138 provided by the filter parameter selection circuit 104. In the example of FIG. 1, AS2 is a digitized version of an analog audio signal (AS1), where ADC 132 provides AS2 based on AS1. The output of the filter circuit 102 is a filtered digital audio signal (AS3) that is converted to a corresponding analog audio signal (AS4) by DAC 128. AS4 is fed into an amplifier 122 to provide an amplified analog audio signal (AS5) for the speaker 124. During speaker operations, voltage and currents measurements for the speaker 124 are collected by a voltage/current sensor 126. These voltage and current measurements are digitized by ADC 130 and provided to the filter parameter selection circuit 104 to perform a back-EMF analysis and/or other operations.

In at least some examples, the filter parameters provided by the filter parameter selection circuit 104 to the filter circuit 102 is dynamically selected. In some examples, selection of different sets of filter parameters 136 and 138 by the filter parameter selection circuit 104 involves various operations including adaptive speaker parameter estimation and determining an audio signal bandwidth estimate based on back-EMF analysis. In system 100, adaptive speaker parameter estimation operations are performed by the parameter options block 108. Meanwhile, operations to determine the audio signal bandwidth estimate are performed by the bandwidth analysis block 106. If the audio signal bandwidth estimate indicates that the audio signal is a wideband audio signal (e.g., a back-EMF impedance transfer function peak magnitude is within a threshold level relative to a target back-EMF impedance transfer function peak magnitude), then a current set of filter parameters 110 determined by the parameter options block 108 is selected and provided to the filter circuit 102 (for use as filter coefficients to define an impulse response or transfer function provided by the filter circuit 102). On the other hand, if the audio signal bandwidth estimate indicates that an audio signal is a narrowband signal (e.g., a back-EMF impedance transfer function peak magnitude is not within a threshold level relative to a target back-EMF impedance transfer function peak magnitude), then a previous set of filter parameters 112 determined by the parameter options block 108 is selected and provided to the filter circuit 102 (for use as filter coefficients to define an impulse response or transfer function provided by the filter circuit 102). In some examples, a scaling factor 114 is applied to the selected set of filter parameters to be provided to the filter circuit 102. The scaling factor 114 is applied, for example, in response to a condition detected by a condition detection block 116. In some examples, the condition detection block 116 computes a Q-factor to determine the scaling. In one example, the Q-factor is given as:

$$Q - factor = \frac{1}{( {R}_{ms} + \frac{{Bl}^{2}}{{R}_{E}} )} \sqrt{\frac{{M}_{ms}}{{C}_{ms}}} , \qquad Equation ( 4 )$$

where R_{E} is the DC resistance of the speaker 124 and the other values are described for Equation 1. In some examples, the scaling factor 114 and/or operations of the condition detection block 116 are based on speaker test results (e.g., factory test results).

In different examples, the filter circuit 102, the filter parameter selection circuit 104, the DAC 128, the amplifier 122, the voltage/current sensor 126, and the ADC 130 are part of one or more integrated circuits. FIG. 2 shows a block diagram 200 of system components in accordance with various examples. In block diagram 200, a DSP 202 in communication with a memory 204 (e.g., RAM, ROM, flash memory) is represented, where the memory 204 stores filter instructions 102A and filter parameter selection instructions 104A to perform the operations described for the filter circuit 102 and the filter parameter selection circuit 104 of FIG. 1. In some examples, the DSP 202 corresponds to a specialized microprocessor for use in an audio signal processing scenario. In other examples, a general-purpose processor or other programmable component is used instead of the DSP 202. In some examples, the memory 204 is separate from the DSP 202 as represented in FIG. 2. In other examples, the memory 204 is part of the DSP 202. In different examples, the DSP 202 and the memory 204 correspond to one or more integrated circuits. In operation, the DSP 202 receives AS2 and outputs AS3 (see FIG. 1), where AS3 is a filtered version of AS2, and where filtering operations are based in part on a set of filter parameters selected as described herein.

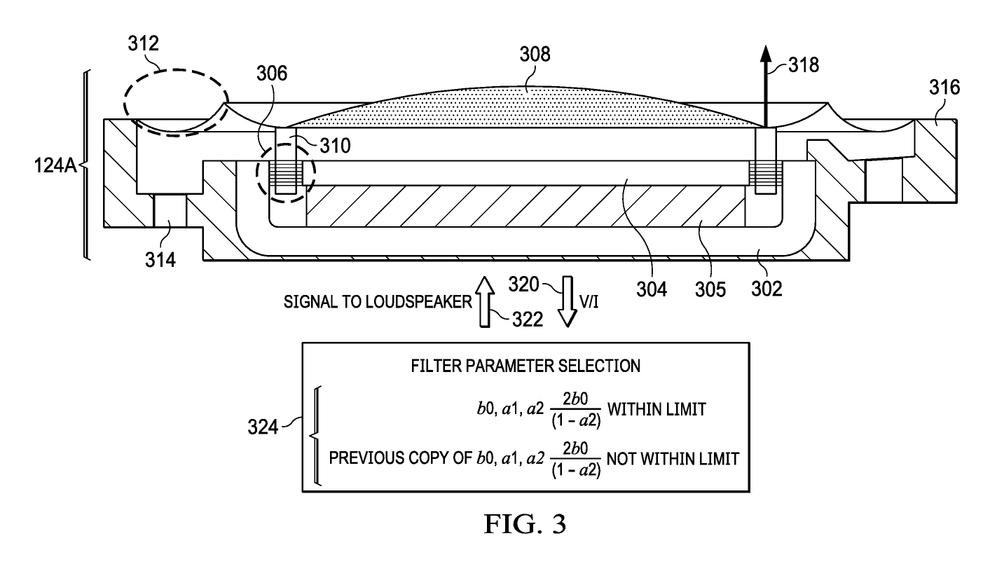

FIG. 3 shows a cross-sectional view of a speaker 124A and a filter parameter selection block 324 for the speaker 124A in accordance with various examples. The speaker 124A of FIG. 3 is an example of the speaker 124 in FIG. 1, and the filter parameter selection block 324 represents hardware and/or software to perform a filter parameter selection algorithm such as the filter parameter selection algorithm given in the filter parameter selection block 324. In at least some embodiments, the filter parameter selection block 324 corresponds to the filter parameter selection circuit 104 of FIG. 1. The purpose of the filter parameter selection block 324 is to provide excursion control for a speaker by selecting filter parameters based on an audio signal bandwidth estimate obtained from back-EMF analysis and related operations as described herein.

As shown, the speaker 124A comprises a voice coil 310 that surrounds a magnet 305, where magnetic circuit components 302 and 304 result in a magnetic field 306 that interacts with the voice coil 310. A diaphragm 308 is attached to the voice coil 310 and to a frame 316. During operations of the speaker 124A, the diaphragm 308 has a directional displacement 318 due to movement of the voice coil 310 and the characteristics (e.g., rigidity/flexibility) of suspension material 312 between the diaphragm 308 and the frame 316. Due to electrical resistance of the voice coil 310 and movement of the diaphragm 308 and suspension material 312, heat and/or mechanical wear is generated during operations of the speaker 124A.

The excursion control provided using the filter parameter selection block 324 and related components prevents mechanical and/or heat-based damage to components of the speaker 124A based on adaptive speaker parameter estimation and narrowband stabilization. Also, as desired, the frame 316 includes ventilation gaps 314 to help move heat away from the diaphragm 308 and/or other components of the speaker 124A. In some examples, the filter parameter selection algorithm employed by the filter parameter selection block 324 is given as:

$$\{ \begin{matrix}\begin{matrix}b 0 , a 1 , a 2 , \frac{2 {b}_{0}}{( 1 - a 2 )} within threshold \\ previous copy of b 0 , a 1 , a 2 , \frac{2 {b}_{0}}{( 1 - a 2 )}\end{matrix} \\ not within threshold\end{matrix} , \qquad Equation ( 5 )$$

In Equation 5, b0, a1, a2 correspond to current set of filter parameters obtained using adaptive speaker parameter estimation. Meanwhile, the previous copy of b0, a1, a2 corresponds to a previous set of filter parameter obtained using adaptive speaker parameter estimation. As shown in Equation 5, an example filter parameter selection algorithm selects b0, a1, a2 as the set of filter parameters when

$$\frac{2 b 0}{( 1 - a 2 )}$$

is within a predetermined threshold. On the other hand, the example filter parameter selection algorithm selects a previous copy of b0, a1, a2 as the set of filter parameters when

$$\frac{2 b 0}{( 1 - a 2 )}$$

is not within the predetermined threshold. The value of

$$\frac{2 b 0}{( 1 - a 2 )}$$

corresponds to the peak value of a back-EMF impedance transfer function or filter, where the peak value indicates whether an audio signal is designated as a broadband signal or a narrowband signal

$$( e . g . , {H}_{BEMF \_ Peak} = \frac{{Bl}^{2}}{{R}_{ms}} = \frac{2 {b}_{0}}{1 - {a}_{2}} ) .$$

In some examples, if

$$\frac{{Bl}^{ 2}}{{R}_{ms}} ( 1 - Δ ) \leq \frac{2 b 0}{( 1 - a 2 )} \leq \frac{{Bl}^{ 2}}{{R}_{ms}} ( 1 + Δ ) ,$$

the input audio signal is designated as a wideband signal, and the current set of filter parameters (e.g., b0, a1, a2) obtained from an adaptive speaker parameter estimation process are selected for use with an excursion control filter. On the other hand, if

$$\frac{2 b 0}{( 1 - a 2 )} > \frac{{Bl}^{ 2}}{{R}_{ms}} ( 1 + Δ ) , or \frac{2 b 0}{( 1 - a 2 )} < \frac{{Bl}^{ 2}}{{R}_{ms}} ( 1 - Δ ) ,$$

then the input audio signal is designated as a narrowband signal. In such case, the most recent filter parameters obtained from a wideband audio signal (e.g., a previous copy of b0, a1, a2) are selected for use with an excursion control filter. As previously discussed, in some examples, Bl and Rₘₛ are measured using a sample speaker from a speaker lot, and Δ is selected so that the variation of

$$\frac{{Bl}^{ 2}}{{R}_{ms}}$$

across the speaker lot, temperature and aging is within Δ. Again, in some examples, Δ depends on Rₘₛ and is typically around 20%. Also, in some examples, Δ is set based on available reliability/aging test data for a given speaker type or speaker lot.

In some examples, operations of the filter parameter selection block 324 and/or related adaptive speaker parameter estimation is performed using voltage and current measurements from the speaker 124A. As desired, a voice coil resistance related to the voice coil 310 is determined from the voltage and current measurements, and is used for adaptive speaker parameter estimation. In FIG. 3, the voltage measurements, current measurements, and/or voice coil resistance measurements are represented by arrow 320.

The output of the filter parameter selection block 324 (e.g., b0, a1, a2 or a previous copy of b0, a1, a2) is used to produce an audio signal represented by arrow 322 for the speaker 124A. The audio signal results in current passing through the voice coil 310, which causes displacement 318 of the voice coil 310 in presence of a magnetic field. The displacement 318 of the voice coil 310 results in movement of the diaphragm 308, which produces audible sound. With the operations of the filter parameter selection block 324, the current to the voice coil 310 is based on adaptive speaker parameter estimation while accounting for issues related to narrowband audio signals as described herein.

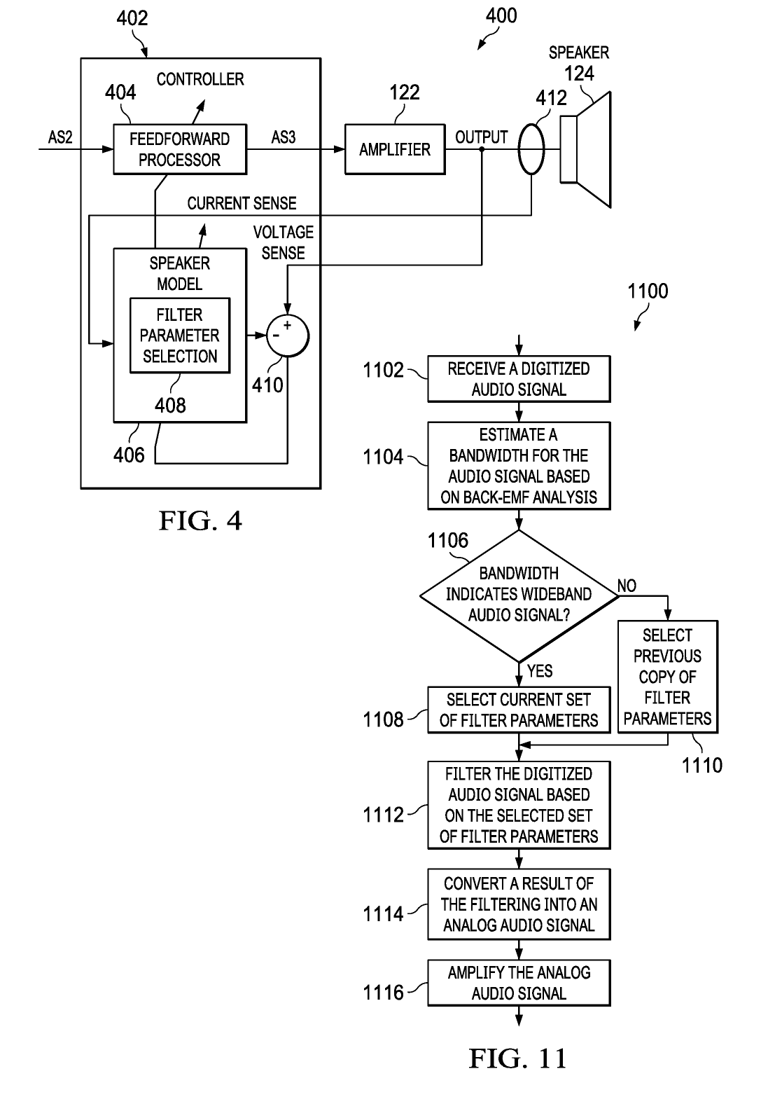

FIG. 4 shows another block diagram of an audio system 400 in accordance with various examples. As shown, the audio system 400 comprises the amplifier 122 and the speaker 124 introduced in FIG. 1. In addition, the audio system 400 comprises a controller 402 that adjusts an input audio signal before it is amplified by the amplifier 122 (e.g., outputting AS3 based on AS2). More specifically, the controller 402 includes a feedforward processor 404, a speaker model block 406, and a compare node 410. In at least some examples, the speaker model block 406 includes a filter parameter selection block 408. In some examples, the filter parameter selection block 408 corresponds to the filter parameter selection circuit 104 of FIG. 1, the filter parameter selection instructions 104A of FIG. 2, and/or the filter parameter selection block 324 of FIG. 3. Also, in some examples, the feedforward processor 404 corresponds to or includes the filter circuit 102 of FIG. 1 and/or the filter instructions 102A of FIG. 2.

In operation, the feedforward processor 404 performs a filter or power compression operation on the input audio data (e.g., AS2) based on parameters provided by the speaker model block 406. The parameters provided by the speaker model block 406 are based on adaptive speaker parameter estimations operations and filter parameter selection operations. In at least some examples, the speaker model block 406 performs adaptive speaker parameter estimation and selects a set of filter parameters (e.g., a current version of b0, a1, a2, or a previous copy of b0, a1, a2) as described herein. Also, it should be understood that the speaker model block 406 continues to adapt even in a narrowband audio signal scenario by using a previous copy of the filter parameters with the adaptation algorithm. By using a previous copy of the filter parameters in a narrowband audio signal scenario, the adaptive speaker parameter estimation is more constrained.

In at least some examples, adaptive speaker parameter estimation during narrowband audio signal scenarios involves fixing the value of less sensitive parameters (e.g., Rms) and tracking the value of more sensitive parameters (e.g., Cms). This is accomplished by using a previous copy of the filter parameters b0, a1, a2 during a narrowband audio signal scenario, where the b0, a1 and a2 values implicitly contain the speaker parameters Cms, Rms, etc. Accordingly, speaker parameter estimation in a narrowband audio signal scenario becomes constrained (i.e. the range of Bl²/Rms is narrowed down to +/−Δ). This process constrains Rms to a fixed value while allowing Cms to still be adapted or “tracked.” In a broadband audio signal scenario (i.e. when Bl²/Rms is within +/−Δ), there is no previous copy of b0, a1 and a2, so all parameters are adapted with equal weightage or sensitivity.

As previously noted, the feedforward processor 404 performs a filter or power compression operation on the input audio data (e.g., AS2) based on the parameters from the speaker model block 406. The output of the feedforward processor 404 is an audio signal (e.g., AS3) to be amplified. The amplifier 122 receives an analog audio signal (e.g., a DAC converts AS3 to an analog audio signal) based on the output from the feedforward processor 404 and amplifies the analog audio signal for input to the speaker 124. During speaker operations, measurements of the voltage and current along the conductive path between the amplifier 122 and the speaker 124 are obtained, and digitized versions of these measurements are provided to the speaker model block 406. In some examples, the speaker model block 406 receives a voltage error value from the compare node 410 (relative to an expected voltage value determined by the speaker model block 406) and a current value as represented in FIG. 4. In some examples, the voltage error value and the current value are used by the speaker model block 406 to select filter parameters for the feedforward processor 404.

More specifically, filter parameters for the feedforward processor 404 are determined by the filter parameter selection block 408 using an audio signal bandwidth estimate obtained from back-EMF analysis. In some examples, the back-EMF analysis uses the frequency of the back-EMF value and/or the current value to determine the audio signal bandwidth estimate (e.g., based on Equations 2 and 3). In some examples, the audio signal bandwidth estimate corresponds to a back-EMF impedance transfer function peak magnitude. When compared to a threshold the

$$( e . g . , \frac{{Bl}^{ 2}}{{R}_{ms}} ( 1 - Δ ) \leq \frac{2 b 0}{( 1 - a 2 )} \leq \frac{{Bl}^{ 2}}{{R}_{ms}} ( 1 + Δ ) ,$$

audio signal bandwidth estimate indicated whether an audio signal is a narrowband audio signal or wideband audio signal. If the audio signal bandwidth estimate indicates a wideband audio signal

$$( e . g . , if \frac{{Bl}^{ 2}}{{R}_{ms}} ( 1 - Δ ) \leq \frac{2 b 0}{( 1 - a 2 )} \leq \frac{{Bl}^{ 2}}{{R}_{ms}} ( 1 + Δ ) is true ) ,$$

the speaker model block 406 provides a current set of filter parameters (e.g., b0, b1, b2) to the feedforward processor 404. On the other hand, if the audio signal bandwidth estimate indicates a narrowband audio signal

$$( e . g . , if \frac{{Bl}^{ 2}}{{R}_{ms}} ( 1 - Δ ) \leq \frac{2 b 0}{( 1 - a 2 )} \leq \frac{{Bl}^{ 2}}{{R}_{ms}} ( 1 + Δ ) is not true ) ,$$

the speaker model block 406 provides a previous set of filter parameters (e.g., a previous copy of b0, a1, a2) to the feedforward processor 404. For the audio system 400, the current set and previous set of filter parameters are determined by the speaker model block 406 using adaptive speaker parameter estimation, where each set of filter parameters associated with a wideband audio signal is stored for later use (e.g., one or more previous sets of filter parameters associated with a wideband audio signal are stored by the speaker model block 406).

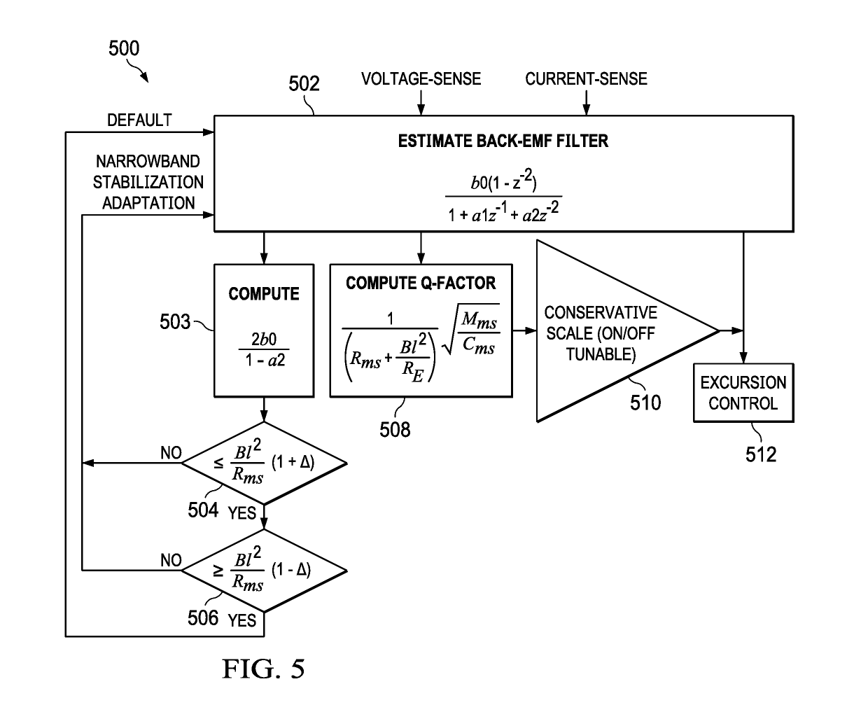

FIG. 5 shows a flowchart of an excursion control method 500 in accordance with various examples. As shown, the method 500 comprises estimating a back-EMF impedance transfer function or filter at block 502. In at least some examples, the back-EMF filter is estimated using Equation 2. At block 503,

$$\frac{2 b 0}{( 1 - a 2 )}$$

is computed. At decision block 504, a determination is made regarding whether

$$\frac{2 b 0}{( 1 - a 2 )} \leq \frac{{Bl}^{ 2}}{{R}_{ms}} ( 1 + Δ ) .$$

If so, a determination is made regarding whether

$$\frac{{Bl}^{ 2}}{{R}_{ms}} ( 1 - Δ ) \leq \frac{2 b 0}{( 1 - a 2 )}$$

at decision block 506. If so, the back-EMF filter of block 502 is updated using a default adaptation for wideband audio signals. If either of the decision blocks 504 and 506 have a negative result

$$( e . g . , if \frac{2 b 0}{( 1 - a 2 )} \leq \frac{{Bl}^{ 2}}{{R}_{ms}} ( 1 + Δ ) is not true , or \frac{{Bl}^{ 2}}{{R}_{ms}} ( 1 - Δ ) \leq \frac{2 b 0}{( 1 - a 2 )} is not true ) ,$$

the back-EMF filter of block 502 is updated using a narrowband stabilization adaptation based on a previous set of filter parameters (e.g., the back-EMF filter of block 502 is updated based on the most recent set of filter parameters obtained from a wideband audio signal).

At block 508, a Q-factor is determined using Equation 4. The Q-factor determined at block 508 is used to select a tunable scaling factor at block 510. At block 512, excursion control is performed based on the back-EMF filter of block 502 and the scaling factor of block 510. The excursion control operations of block 512 prevent mechanical damage to a speaker (e.g., the speaker 124 of FIGS. 1 and 4, or the speaker 124A of FIG. 3).

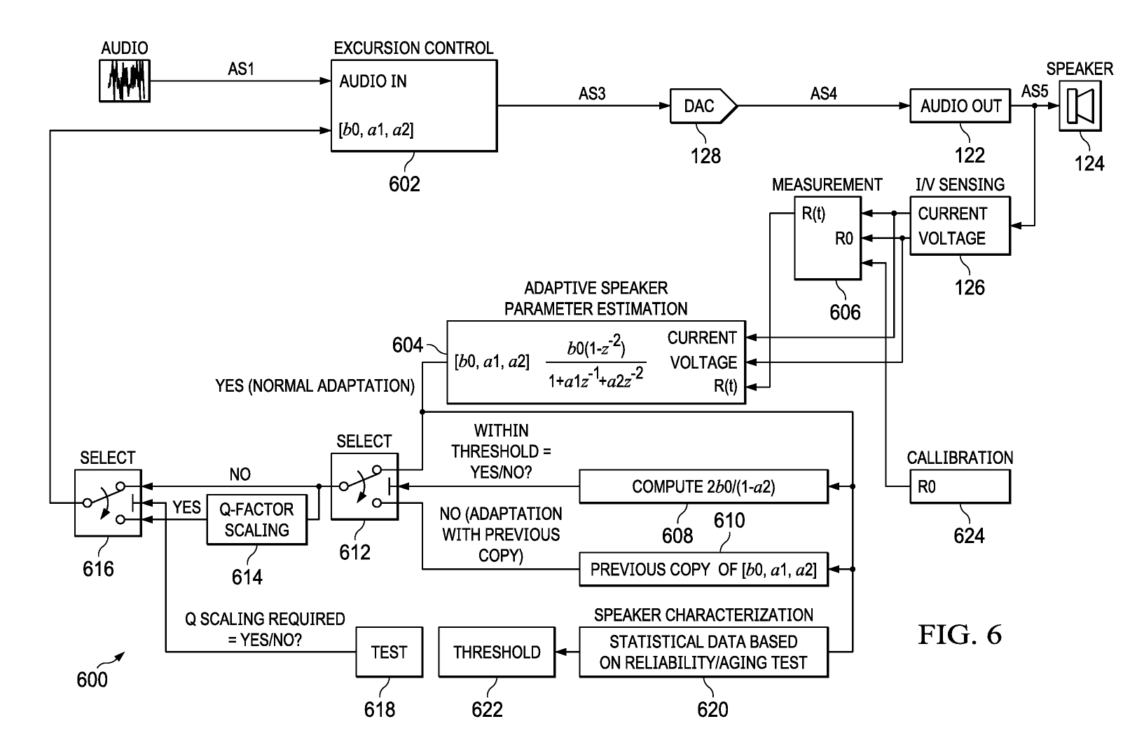

FIG. 6 shows an audio amplification system 600 in accordance with various examples. As shown, the audio amplification system 600 includes the amplifier 122, the speaker 124, and the voltage/current sensor 126, and the DAC 128 introduced in FIG. 1. The audio amplification system 600 also includes an excursion control block 602 that receives an input audio signal (e.g., AS2) and provides an output audio signal (e.g., AS3). In at least some examples, the excursion control block 602 is an example of the filter circuit 102 introduced in FIG. 1, the filter instructions 102A in FIG. 2, and/or the feedforward processor 404 of FIG. 4, where the operations of the excursion control block 602 are based on the filter parameters (e.g., b0, a1, a2, or a previous copy of b0, a1, a2). During operations of the speaker 124, updated values for the filter parameters are provided to the excursion control block 602, which performs excursion control by adjusting the input audio signal. In different examples, the excursion control block 602 adjusts the input audio signal to balance speaker loudness and speaker protection, where the specific balance employed for different audio amplification systems varies. Also, in some examples, the excursion control block 602 adjusts this balance to account for changes to the speaker 124 over time.

In the audio amplification system 600, the filter parameters are determined using various components including the voltage/current sensor 126, an adaptive speaker parameter estimation block 604, and a calculation block 606. These components and/or others represented in FIG. 6 are an example of the filter parameter selection circuit 104 of FIG. 1, the filter parameter selection instructions 104A of FIG. 2, the filter parameter selection block 324 of FIG. 3, and/or the speaker model block 406 of FIG. 4. More specifically, the voltage/current sensor 126 obtains voltage and current measurements from a conductive path between the amplifier 122 and the speaker 124. The voltage and current measurements are provided to the calculation block 606, which uses the voltage and current measurements and a base resistance (RO) for the speaker 124 to determine a voice coil resistance, R(t). More specifically, in some examples, R(t) is a function of an estimated voice coil temperature obtained from the voltage and current measurements and RO. In some examples, RO is provided to the calculation block 606 by a calibration block 624 (e.g., RO is determined by a calibration process for the speaker 124 or a related speaker).

The voltage measurements, the current measurements, and R(t) values are provided to an adaptive speaker parameter estimation block 604, which determines a current set of filter parameters (b0, a1, a2) for the current audio signal represented by the voltage and current measurements. If the audio signal represented by the voltage and current measurements is determined to be a wideband audio signal, the current set of filter parameters (b0, a1, a2) are selected by selection block 612, and are provided to the excursion control block 602. Otherwise, if the audio signal represented by the voltage and current measurements is determined to be a narrowband audio signal, a previous set of filter parameters (a previous copy of b0, a1, a2 related to the most recent wideband audio signal) is selected by the selection block 612, and are provided to the excursion control block 602.

In some examples, an audio signal bandwidth estimate and thresholds are obtained using back-EMF analysis as described herein. In the audio amplification system 600, a value for

$$\frac{2 b 0}{( 1 - a 2 )}$$

is determined at block 608, where the values for b0 and a2 are provided by the adaptive speaker parameter estimation block 604. Also, a previous copy of values for b0, a1, and a2 are stored at block 610, where the values for b0, a1, and a2 are provided by the adaptive speaker parameter estimation block 604. In some examples, the value for

$$\frac{2 b 0}{( 1 - a 2 )} ,$$

obtained at block 608, is also used to determine whether to overwrite a previous copy of b0, a1, and a2 with a current copy of b0, a1, and a2. More specifically, if

$$\frac{2 b 0}{( 1 - a 2 )}$$

is within a threshold

$$( e . g . , \frac{{Bl}^{ 2}}{{R}_{ms}} ( 1 - Δ ) \leq \frac{2 b 0}{( 1 - a 2 )} \leq \frac{{Bl}^{ 2}}{{R}_{ms}} ( 1 + Δ ) ) ,$$

the current audio signal is designated as a wideband signal, and the current values for b0, a1, and a2 determined by block 604 are selected by the selection block 612, and are provided to block 610 for later use as needed (the current values for b0, a1, and a2 become the previous copy of b0, a1, and a2 in the next iteration). Otherwise, if

$$\frac{2 b 0}{( 1 - a 2 )}$$

is not within the threshold, the current audio signal is designated as a narrowband signal, and the current values for b0, a1, and a2 determined by block 604 are not selected by the selection block 612, and are not provided to block 610. In such case, the previous copy of b0, a1, and a2 stored by block 610 (corresponding to the latest filter parameters for a wideband audio signal) are selected by the selection block 612. In some examples, the threshold used to determine if an audio signal is narrowband or wideband is stored at block 622. As needed, the threshold value is updated using speaker characterization block 620. In some examples, the speaker characterization block 620 determines the threshold based on reliability/aging test results and statistical data.

The output of the selection block 612 is selectively scaled using a scaling block 614 and selection block 616. In some examples, the scaling block 614 applies a Q-factor scaling value (e.g., see Equation 4) to the output of the selection block 612. Also, the selection block 616 operates based on a control signal from a test block 618, where the control signal from the test block 618 is based on previous test results for the speaker 124 or a related speaker.

In some examples, the operations represented by blocks 604, 608, 610, and 612 correspond to Equations 3 and 5 described previously. Also, in some examples, the operations represented by block 614 correspond to Equation 4 described previously. In different examples, the various operational or value blocks (e.g., blocks 602, 604, 606, 608, 610, 612, 614, 616, 618, 620, 622, 624) represented for the audio amplification system 600 correspond to hardware implementation components (e.g., circuitry to perform specific operations and/or to store specific values) and/or a software implementation components (e.g., a processor coupled to a memory with stored values and/or instructions).

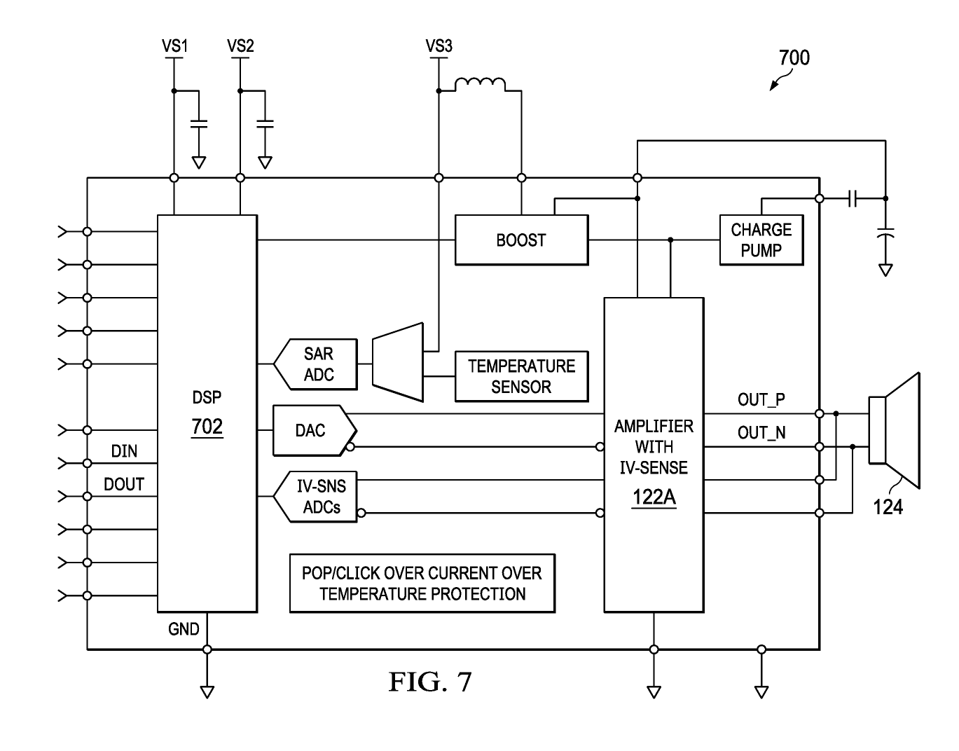

FIG. 7 shows an amplifier device 700 in accordance with various examples. As shown, the amplifier device 700 includes a DSP 702. In some examples, the DSP 702 corresponds to or performs the operations of the filter circuit 102 and the filter parameter selection circuit 104 of FIG. 1. In some examples, the DSP 702 corresponds to or performs the operations of the DSP 202 of FIG. 2. In some examples, the DSP 702 performs the filter parameter selection algorithm represented in the filter parameter selection block 324 of FIG. 3. In some examples, the DSP 702 corresponds to or performs the operations of at least the feedforward processor 404 and the speaker model block 406 of FIG. 4. In some examples, the DSP 702 corresponds to or performs the operations of at least the excursion control block 602, the adaptive speaker parameter estimation block 602, the calculation block 606, the selection block 612, and the selection block 616 of FIG. 6.

In FIG. 7, the DSP 702 is powered by one or more voltage supply signals (e.g., VS1 and VS2) and couples to ground. In operation, the DSP 702 receives an input data stream (DIN) corresponding to an audio signal (e.g., AS2) and provides an output signal to an amplifier 122A (e.g., an example of amplifier 122), where the amplifier 122A includes voltage/current sensing. In some examples, the DSP 702 also provides an output data stream (DOUT) to communicate with other components outside the amplifier device 700. In different examples, the DSP 702 includes other inputs such as clock signals and control signals. As shown, the amplifier device 700 of FIG. 7 includes other components such as ADCs, DACs, voltage supply circuitry, a multiplexer, a temperature sensor, a boost circuit, a charge pump, and an overcurrent/overtemp protection circuit. In other amplifier device examples, one or more of these other components are omitted. Also, in some amplifier device examples, other components are used. In FIG. 7, the amplifier 122A provides differential output signals (OUT_P and OUT_N) to the speaker 124. Also, differential sense inputs are received by the amplifier 122A from the conductive paths between the amplifier 122A and the speaker 124. The differential sense inputs are used to determine voltage and current measurements. As desired, amplifier devices such as the amplifier device 700 of FIG. 7 are included with a mobile device with a speaker (e.g., a cellular phone or tablet) to balance excursion control and loudness of the speaker as described herein.

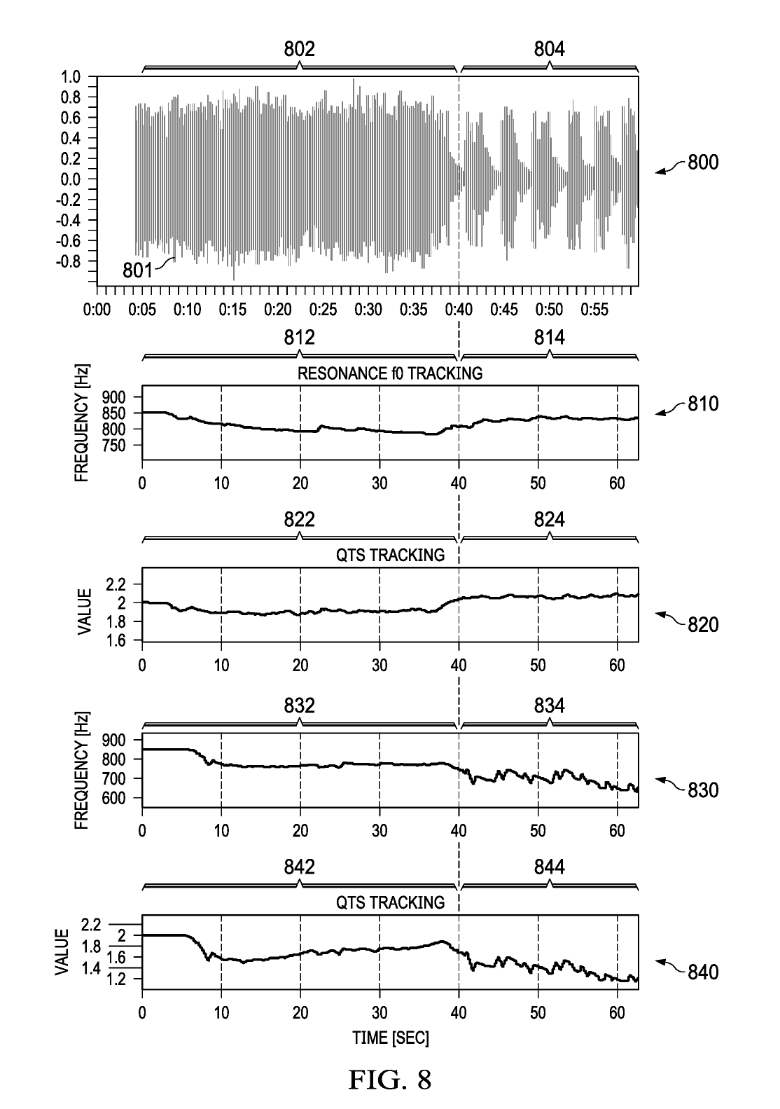

FIG. 8 shows graphs comparing broadband and narrowband portions of an audio signal and related filter parameter tracking with and without narrowband stabilization in accordance with various examples. As used herein, “narrowband stabilization” refers to the filter parameter selection process described herein (e.g., operations related to the filter parameter selection circuit 104 of FIG. 1, the filter parameter selection instructions 104A of FIG. 2, the filter parameter selection block 324 of FIG. 3, the speaker model block 406 of FIG. 4, the method 500 of FIG. 5, various components of FIG. 6, and/or the DSP 702 of FIG. 7). More specifically, graph 800 shows an audio signal 801 as a function of time, where the audio signal 801 has a wideband portion 802 (from approximately 0-40 seconds) and a narrowband board 804 (starting after 40 seconds). In graph 810, a resonant frequency (f0) for a speaker is tracked over the same time period as represented in graph 800 with narrowband stabilization being used. In graph 820, another speaker parameter (Qts) is tracked over the same time period as represented in graph 800 with narrowband stabilization being used. In graph 830, f0 is tracked over the same time period as represented in graph 800 without narrowband stabilization being used. In graph 840, Qts is tracked over the same time period as represented in graph 800 without narrowband stabilization being used. As represented in graphs 810 and 820, use of narrowband stabilization results in f0 and Qts being sufficiently stable even during the narrowband portion 804 of the audio signal 801 (e.g., all values for f0 are within approximately 60 Hz of each other). When the stability and accuracy of f0 and Qts are sufficient as represented in graphs 810 and 820, excursion control operations (e.g., performed by the excursion control block 602) prevent over excursion of a speaker (e.g., the speaker 124). Without narrowband stabilization, f0 and Qts are not sufficiently stable during the narrowband portion 804 of the audio signal 801 as represented in graphs 830 and 840 (e.g., some values for f0 vary by as much as 200 Hz). In such situations, excursion control operations do not work properly.

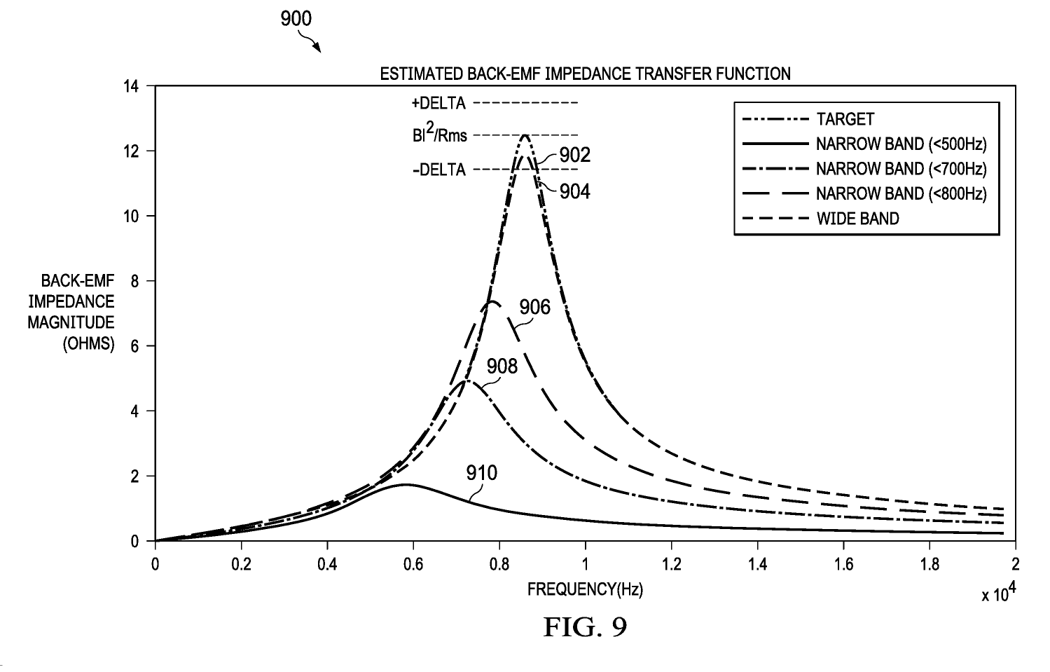

FIG. 9 shows a graph 900 representing adaptation behavior without narrowband stabilization. In graph 900, curves 902, 904, 906, 908, and 910 represent a target back-EMF impedance transfer function and back-EMF impedance transfer functions for audio signals with different bandwidths. More specifically, curve 902 shows a target back-EMF impedance transfer function, curve 904 shows back-EMF impedance magnitude as a function of frequency for a wideband audio signal, curve 906 shows back-EMF impedance magnitude as a function of frequency for a first narrowband audio signal (e.g., less than 800 Hz), curve 908 shows back-EMF impedance magnitude as a function of frequency for a second narrowband audio signal (e.g., less than 700 Hz), and curve 910 shows back-EMF impedance magnitude as a function of frequency for a third narrowband audio signal (e.g., less than 500 Hz). As represented in graph 900, without narrowband stabilization, the back-EMF impedance transfer functions for the narrowband audio signals corresponding to curves 906, 908, and 910 significantly vary from the target back-EMF impedance transfer function corresponding to curve 902 (only the curve 904 corresponding to a wideband audio signal closely resembles the target back-EMF impedance transfer function).

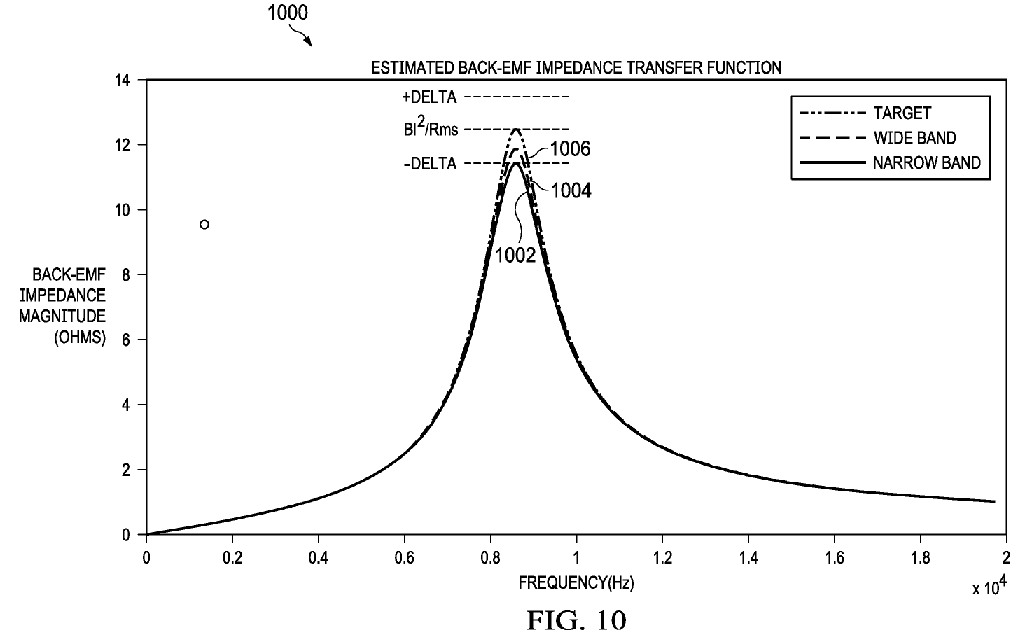

FIG. 10 shows a graph 1000 representing adaptation behavior with narrowband stabilization. In graph 1000, curves 1002, 1004, and 1006 represent a target back-EMF impedance transfer function and back-EMF impedance transfer functions for audio signals with different bandwidths. More specifically, curve 1006 shows a target back-EMF impedance transfer function, curve 1004 shows back-EMF impedance magnitude as a function of frequency for a wideband audio signal, curve 1002 shows back-EMF impedance magnitude as a function of frequency for a narrowband audio signal. As represented in graph 1000, with narrowband stabilization, the back-EMF impedance transfer functions for a wideband audio signal corresponding to curve 1004 and for a narrowband audio signal corresponding to curve 1002 closely resemble the target back-EMF impedance transfer function corresponding to curve 1006. With narrowband stabilization, the peak magnitudes of curves 1004 and 1002 are within a threshold offset from the peak magnitude of curve 1006.

FIG. 11 shows a flowchart of an audio signal amplification method 1100 in accordance with various examples. As shown, the method 1100 comprises receiving a digitized audio signal at block 1102. At block 1104, a bandwidth for the audio signal is estimated based on back-EMF analysis. If the estimated bandwidth indicates wideband audio signal (decision block 1106), a current set of filter parameters are selected at block 1108. On the other hand, if the estimated bandwidth does not indicate a wideband audio signal (decision block 1106), a previous set of filter parameters are selected at block 1110. At block 1112, the digitized audio signal is filtered based on the selected set of filter parameters (from either block 1108 or block 1110). At block 1114, a result of the filtering is converted into an analog audio signal. At block 1116, the analog audio signal is amplified.

In some examples, the method 1100 comprises calculating the current set of filter parameters and the previous set of filter parameters based on voltage measurements for a speaker, current measurements for the speaker, and estimated resistance values for a voice coil of the speaker. In some examples, the method 1100 comprises obtaining the voltage measurements and the current measurements from a voltage/current sensor as a function of time, and estimating resistance values for the voice coil of the speaker as a function of time. In some examples, the method 1100 comprises comprising scaling the selected set of filter parameters, wherein the filtering is performed using a scaled set of filter parameters. In some examples, the block 1104 comprises determining a back-EMF impedance transfer function, and block 1106 comprises comparing a back-EMF impedance transfer function peak magnitude to a target back-EMF impedance transfer function peak magnitude, where an offset relative to the target back-EMF impedance transfer function peak corresponds to the predetermined threshold.

Certain terms have been used throughout this description and claims to refer to particular system components. As one skilled in the art will appreciate, different parties may refer to a component by different names. This document does not intend to distinguish between components that differ in name but not function. In this disclosure and claims, the terms “including” and “comprising” are used in an open-ended fashion, and thus should be interpreted to mean “including, but not limited to . . . .” Also, the term “couple” or “couples” is intended to mean either an indirect or direct wired or wireless connection. Thus, if a first device couples to a second device, that connection may be through a direct connection or through an indirect connection via other devices and connections. The recitation “based on” is intended to mean “based at least in part on.” Therefore, if X is based on Y, X may be a function of Y and any number of other factors.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A system that comprises:
a filter circuit configured to adjust digitized audio signal values based on filter parameters;
a filter parameter selection circuit configured determine an audio signal bandwidth estimate based on back-EMF analysis and to supply different sets of filter parameters to the filter circuit based on the audio signal bandwidth estimate and a predetermined threshold; and
a digital-to-analog converter (DAC) configured to convert an output of the filter circuit into an analog audio signal to be amplified.

2. The system of claim 1, wherein the filter parameter selection circuit is configured to supply a current set of filter parameters to the filter circuit if the audio signal bandwidth estimate is within the predetermined threshold.

3. The system of claim 1, wherein the filter parameter selection circuit is configured to supply a previous set of filter parameters to the filter circuit if the audio signal bandwidth estimate is not within the predetermined threshold, wherein the previous set of filter parameters is associated with an audio signal having an audio signal bandwidth estimate within the predetermined threshold.

4. The system of claim 1, wherein the filter parameter selection circuit configured to selectively scale a set of filter parameters to be supplied to the filter circuit.

5. The system of claim 1, wherein the audio signal bandwidth estimate comprises a back-EMF impedance transfer function peak magnitude, and wherein the predetermined threshold is an offset value relative to a target back-EMF impedance transfer function peak magnitude.

6. The system of claim 1, wherein each set of filter parameters comprises filter coefficients obtained from adaptive speaker parameter estimation operations performed by the filter parameter selection circuit.

7. The system of claim 6, wherein, in response to the audio signal bandwidth estimate indicating a narrowband audio signal scenario, the adaptive speaker parameter estimation operations are updated to constrain a first parameter and track a second parameter.

8. The system of claim 7, wherein the first parameter is mechanical damping (Rms) and the second parameter is mechanical compliance (Cms).

9. The system of claim 1, further comprising:
a voltage sensor configured to obtain voltage measurements associated with a speaker; and
a current sensor configured to obtain current measurements associated with the speaker, wherein the filter parameter selection circuit performs the back-EMF analysis based on the obtained voltage measurements and current measurements.

10. The system of claim 1, further comprising an amplifier configured to amplify the analog audio signal, wherein the amplifier, the filter circuit, and the filter parameter selection circuit are components of an integrated circuit.

11. An amplifier device that comprises:
circuitry configured to determine an audio signal bandwidth estimate based on back-EMF analysis, to obtain different sets of filter parameters, to select one of the different sets of filter parameters based on the audio signal bandwidth estimate and a predetermined threshold, to perform a filter operation on digitized audio signal values based on a selected one of the different sets of filter parameters, and to output a result of the filter operation; and
a digital-to-analog converter (DAC) configured to convert the result of the filter operation to an analog audio signal; and
an amplifier configured to amplify the analog audio signal.

12. The amplifier device of claim 11, wherein the circuitry comprises a digital signal processor (DSP) and a memory with instructions, wherein the DSP is configured to execute the instructions to determine the audio signal bandwidth estimate, to obtain the different sets of filter parameters, to select one of the different sets of filter parameters, to perform the filter operation, and to output the result of the filter operation.

13. The amplifier device of claim 11, wherein the circuitry comprises
a first circuit configured to determine the audio signal bandwidth estimate based on back-EMF analysis, and to select between different sets of filter parameters based on the audio signal bandwidth estimate and the predetermined threshold; and
a second circuit configured to adjust digitized audio signal values based on the set of filter parameters selected by the first circuit.

14. The amplifier device of claim 11, wherein the circuitry is configured to supply a current set of filter parameters to the filter circuit if the audio signal bandwidth estimate is within the predetermined threshold, and wherein the circuitry is configured to supply a previous set of filter parameters to the filter circuit if the audio signal bandwidth estimate is not within the predetermined threshold.

15. The amplifier device of claim 11, wherein the circuitry is configured to scale a selected set of filter parameters.

16. The amplifier device of claim 11, wherein the audio signal bandwidth estimate comprises a back-EMF impedance transfer function peak magnitude, and wherein the predetermined threshold is an offset value relative to a target back-EMF impedance transfer function peak magnitude.

17. The amplifier device of claim 11, further comprising:
a voltage sensor configured to obtain voltage measurements associated with a speaker; and
a current sensor configured to obtain current measurements associated with the speaker, wherein the circuitry performs the back-EMF analysis based on the obtained voltage measurements and current measurements.

18. An audio signal amplification method that comprises:
receiving a digitized audio signal;
determining if the digitized audio signal is a narrowband audio signal or wideband audio signal based on back-EMF analysis;
in response to determining that the digitized audio signal is a wideband audio signal, selecting a current set of filter parameters;
in response to determining that the digitized audio signal is a narrowband audio signal, selecting a previous set of filter parameters;
filtering the digitized audio signal based on the selected set of filter parameters;
converting a result of the filtering into an analog audio signal; and
amplifying the analog audio signal.

19. The method of claim 18, further comprising calculating the current set of filter parameters and the previous set of filter parameters based on voltage measurements for a speaker, current measurements for the speaker, and estimated resistance values for a voice coil of the speaker.

20. The method of claim 19, further comprising:
obtaining the voltage measurements and the current measurements from a voltage/current sensor as a function of time;
estimating resistance values for the voice coil of the speaker as a function of time; and
performing adaptive speaker parameter estimation based on the voltage measurements, the current measurements, and the estimated resistance values, wherein the different sets of filter parameters are obtained from adaptive speaker parameter estimation operations.

21. The method of claim 20, further comprising constraining adaptive speaker parameter estimation operations relative to default operations in response to determining that the digitized audio signal is a narrowband audio signal.

22. The method of claim 18, wherein determining if the digitized audio signal is a narrowband audio signal or wideband audio signal comprises determining a back-EMF impedance transfer function peak magnitude and comparing the back-EMF impedance transfer function peak magnitude to a target back-EMF impedance transfer function peak magnitude.
